(19) United States
(12) Patent Application Publication
(10) Pub. No.: US 2015/0108038 A1
(43) Pub. Date: Apr. 23, 2015

(54) TAPE AND REEL COVER TAPE TO IMPROVE DIE STICKING ISSUES

(71) Applicant: Texas Instruments Incorporated, Dallas, TX (US)

(72) Inventors: Randy Hsu, New Taipei City (TW); Shawn Wu, New Taipei City (TW); J K Ho, New Taipei City (TW); Debby Hsiao, New Taipei City (TW)

(21) Appl. No.: 14/060,949

(22) Filed: Oct. 23, 2013

(51) Int. Cl. B65D 73/02; H05K 13/00

(52) U.S. Cl. CPC B65D 73/02; H05K 13/0084
USPC 206/714

(57) ABSTRACT

A new type of tape and reel tape based on the cover tape having projections extending from the bottom surface of the cover tape leaving a minimum of adhesive surface exposed to the surface mount die or packages contained in the pocket areas of the carrier tape.

### FIELD OF THE INVENTION

This invention relates to the field of integrated circuits. More particularly, this invention relates to reel and tape packaging for shipment of surface mount devices and the cover tape used to close the carrier tape after the integrated circuit has been inserted into the carrier tape

### BACKGROUND OF THE INVENTION

Wafer level chip size packages, surface mount die and other integrated circuit products are typically shipped in carrier tape and reel wherein every package, surface mount die or product is placed into a separate pocket in the carrier tape. In this way, pick and place mounting equipment on the assembly line can pick the packages or surface mount die out of the pockets and place them directly onto a printed circuit board (PCB).

After the packages or surface mount die are inserted into the pockets on the carrier tape, the carrier tape is then covered with a cover tape, thus closing the pockets and securing the packages or surface mount die in the carrier tape. The carrier tape is then rolled onto a reel that is compatible with pick and place mounting equipment and shipped to the customer.

The customer inserts the reel into the mounting equipment, wherein the mounting equipment removes the cover tape so that the equipment can remove each package or surface mount die from the carrier tape and place them on the PCB for mounting.

Typically the cover tape has adhesive on one side of the cover tape to adhere the cover tape to the carrier tape. The adhesive is continuous over the one entire surface of the tape. During shipment or during the mounting process, the package or surface mount die may adhere themselves to the exposed adhesive over the pocket in the carrier tape. This can cause problems with the mounting equipment during the mounting processes.

In view of the foregoing, there is a need to provide a method of preventing the packages or surface mount die from sticking to the cover tape.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In accordance with an embodiment of the present application, a tape and reel shipping container is provided. The tape and reel shipping container, comprises: a carrier tape covered by a cover tape; the carrier tape is constructed of antistatic material and has two parallel edges with pockets disposed there between; the pockets are separated from the parallel edges and each other, wherein the space between the pockets and the parallel edges is sufficient to provide a good sealing surface, wherein the pockets are configured to hold either packages or surface mount die; wherein, one of the spaces between the pockets and the parallel edges is extended outward to provide space for index holes; the index holes are configured to be connected to an indexing sprocket in either a packaging machine or a surface mount machine; and a cover tape having top and bottom surfaces, projections extending from the bottom surface and adhesive covering the bottom surface of the cover tape; wherein the cover tape seals the packages or surface mount die into the pockets of the carrier tape, thereby protecting the packages or surface mount die during shipment, wherein the cover tape is attached to the carrier tape by the adhesive on the bottom of the cover tape.

### DESCRIPTION OF THE VIEWS OF THE DRAWING

FIG. 1 shows an isometric view of the carrier tape along with the cover tape.

FIG. 2A shows of a plan view of a carrier tape covered by a cover tape of an embodiment of the present invention.

FIG. 2B shows a cross section of the plan view of FIG. 2A at A:A′

In the drawings, like reference numerals are sometimes used to designate like structural elements. It should also be appreciated that the depictions in the figures are diagrammatic and not to scale.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The solution to the problem of the packages or surface mount die sticking to the cover tape is a new type of tape with projections extending from the bottom surface of the cover tape.

A typical cover tape has adhesive over a 100% coverage of the side of the cover tape facing the carrier tape with adhesive thus causing the package or surface mount die to adhere themselves to the exposed adhesive. The purpose of this invention is to prevent the package or surface mount die from adhering themselves to the exposed adhesive over the pocket in the carrier tape that can cause problems with the mounting equipment during the mounting processes.

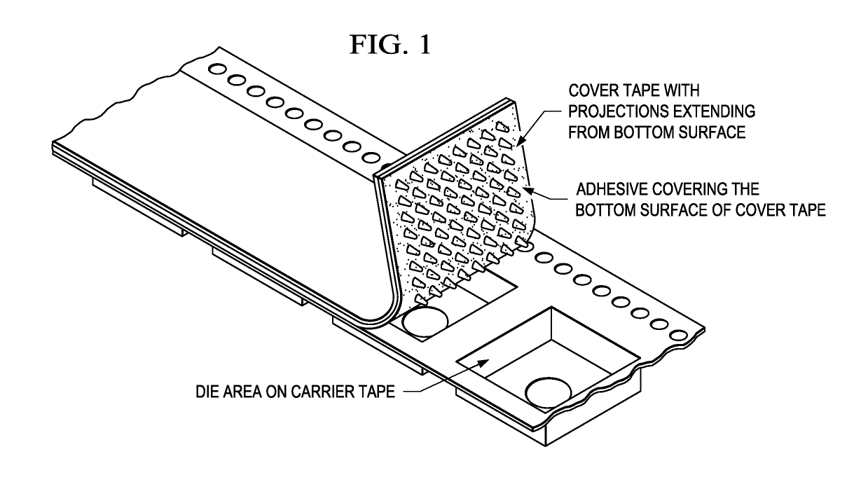

The root cause of packages or surface mount die sticking to the cover tape is 100% coverage of the side of the cover tape facing the carrier tape with adhesive. FIG. 1 shows an isometric view of one embodiment to solve the problem. The cover tape has projections extending from the bottom surface of the cover tape.

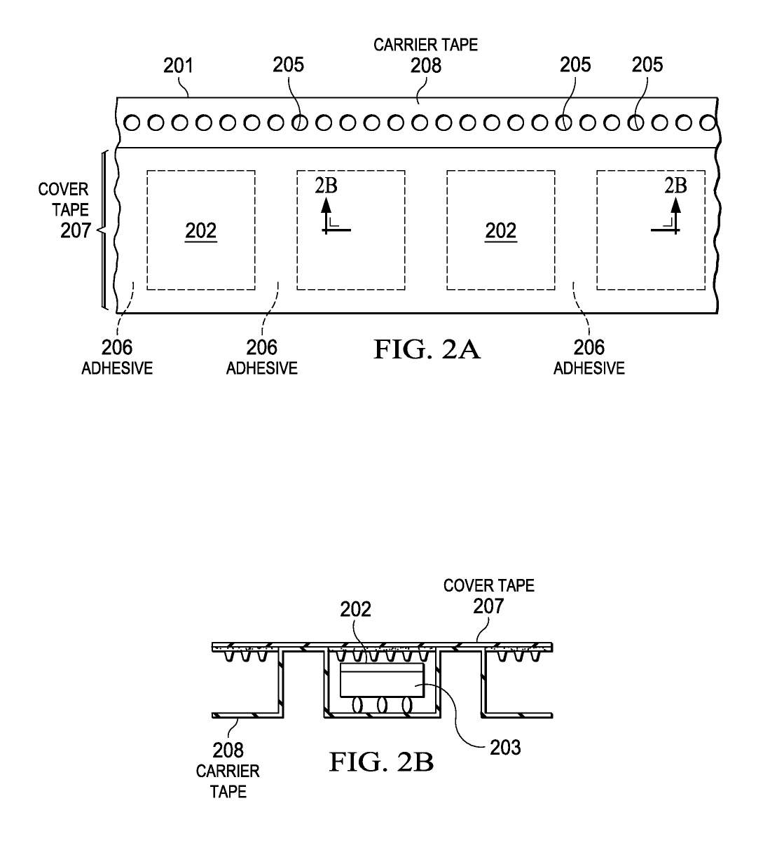

An embodiment of the invention is shown in FIG. 2A. FIG. 2A shows a plan view of a carrier tape 208 covered by a cover tape according to the present invention. The carrier tape 208 is constructed of antistatic material. The carrier tape has two parallel edges 201 with pockets 202 disposed there between for shipping, packages 203 or surface mount die 203. The pockets are separated from the parallel edges and each other, wherein the space 204 between the pockets and the parallel edges and each other is sufficient to provide a good sealing surface. In addition, one or both of the spaces 204 is extended outward to provide space for index holes 205. In this example, the space 204 is only expanded on one side. The index holes 205 supply connection to a indexing sprocket (not shown) in either the packaging machine or the surface mount machine.

A cover tape 207, having top and bottom surfaces, wherein projections extend from the bottom surface of the tape, is provided to seal the packages 203 or surface mount die 203, into the pockets 202 of the carrier tape 208, thereby protecting the packages 203 or surface mount die 203 during shipment. The cover tape 207 is attached to the carrier tape 208 by adhesive 206 on the bottom of the cover tape 207. The cover tape can be composed of an anti-static material or coated with an anti-static compound. The adhesive can be a heat activated adhesive (HAA) ‘dry’ adhesive or pressure sensitive adhesive (PSA).

The projections extending from the bottom of the cover tape can be pyramid shaped, cone shaped or triangular shaped raised-ribs, wherein the triangular shaped raised-rib projections can extend between the edges of the tape in a perpendicular manner or run parallel to the edges of the tape.

FIG. 2B shows a cross section of FIG. 2A at A:A′. It is readily apparent that that the surface area for adhesive 206 located over packages 203 or surface mount die 203 is limited to the peaks of the projection pattern, thus solving the problem of the packages or surface mount die from sticking to the cover tape.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A tape and reel shipping container, comprising:
a carrier tape covered by a cover tape;
the carrier tape is constructed of antistatic material and has two parallel edges with pockets disposed there between;
the pockets are separated from the parallel edges and each other, wherein the space between the pockets and the parallel edges and each other is sufficient to provide a good sealing surface, wherein the pockets are configured to hold either packages or surface mount die;
wherein, one of the spaces between the pockets and the parallel edges is extended outward to provide space for index holes;
the index holes are configured to be connected to an indexing sprocket in either a packaging machine or a surface mount machine; and
a cover tape having top and bottom surfaces, projections extending from the bottom surface of the cover tape and adhesive covering the bottom surface of the cover tape;
wherein the cover tape seals the packages or surface mount die into the pockets of the carrier tape, thereby protecting the packages or surface mount die during shipment, wherein the cover tape is attached to the carrier tape by the adhesive on the bottom of the cover tape.

2. The tape and reel shipping container of claim 1, wherein the cover tape is composed of an anti-static material or coated with an anti-static compound.

3. The tape and reel shipping container of claim 1, wherein the cover tape adhesive is selected from heat activated adhesive (HAA) ‘dry’ adhesive or pressure sensitive adhesive (PSA).

4. The tape and reel shipping container of claim 1, wherein the shape of the projections extending from the bottom of the cover tape is selected from pyramid shaped, cone shaped or triangular shaped raised-ribs, wherein the triangular shaped raised-rib projections extend between the edges of the tape in a perpendicular manner or run parallel to the edges of the tape.
